(19) United States
(12) Patent Application Publication
(10) Pub. No.: US 2005/0281100 A1
(43) Pub. Date: Dec. 22, 2005

(54) Mail item

(76) Inventor: Raymond John Herbert, Essex (GB)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 10/503,037

(22) PCT Filed: Jan. 31, 2003
(86) PCT No.: PCT/GB03/00393

§ 371 Date: Aug. 4, 2005

(30) Foreign Application Priority Data
Jan. 31, 2002 (GB) 0202255.6

(51) Int. Cl. G11C 29/00

(52) U.S. Cl. 365/200

(57) ABSTRACT

A mail item incorporating an information block which provides a three-dimensional array of addressable data elements for storing information, wherein the thee-dimensional array defines a plurality of layers to which information can be written.

The present invention relates to a mail item, in particular a re-usable mail item.

Mail items are printed with information, increasingly with bar codes, as one-dimensional or two-dimensional information blocks.

It is an aim of the present invention to provide a mail item which incorporates an information block which provides a three-dimensional array of addressable data elements for storing information, and in particular a mail item which is re-usable, such that, on each use, information is written to a different layer of the information block. The present applicant has recognized that optical memory, such as disclosed in U.S. Pat. No. 5,268,862 and U.S. Pat. No. 5,472,759, the contents of which are herein incorporated by reference, could be adapted for use in a mail item.

In one aspect the present invention provides a mail item incorporating an information block which provides a three-dimensional array of addressable data elements for storing information, wherein the three-dimensional array defines a plurality of layers to which information can be written.

Preferably, the information block comprises a carrier including a photochromic storage material having first and second states, and a readout material for providing an indication of the state of the storage material at its location.

Preferably, the stored information includes encoded information.

In one embodiment the encoded information is encrypted information.

In another embodiment the encoded information is cryptographically-signed information.

In one embodiment the information block comprises an applied coating.

In another embodiment the information block defines at least part of a body of the mail item.

In one embodiment the mail item comprises a container.

In another embodiment the mail item comprises an envelope.

Preferably, the mail item is re-usable, such that, on each use, information is written to a different layer of the information block.

In another aspect the present invention relates to use, as a re-usable item, of a mail item incorporating an information block which provides a three-dimensional array of addressable data elements for storing information, with the three-dimensional array defining a plurality of layers to which information can be written.

In a further aspect the present invention provides a mail handling system, comprising: an information reader for reading information from an information block, as a three-dimensional array of addressable data elements, incorporated in a mail item, with the three-dimensional array defining a plurality of layers to which information can be written, and identifying the last written layer in which information is stored; and an information writer for writing new information in a subsequent layer of the three-dimensional array of the information block.

Preferably, the information writer is configured such as to over-write the last written layer of the three-dimensional array of the information block and thereby zeroise that layer.

Preferred embodiments of the present invention will now be described hereinbelow by way of example only with reference to the accompanying drawings, in which:

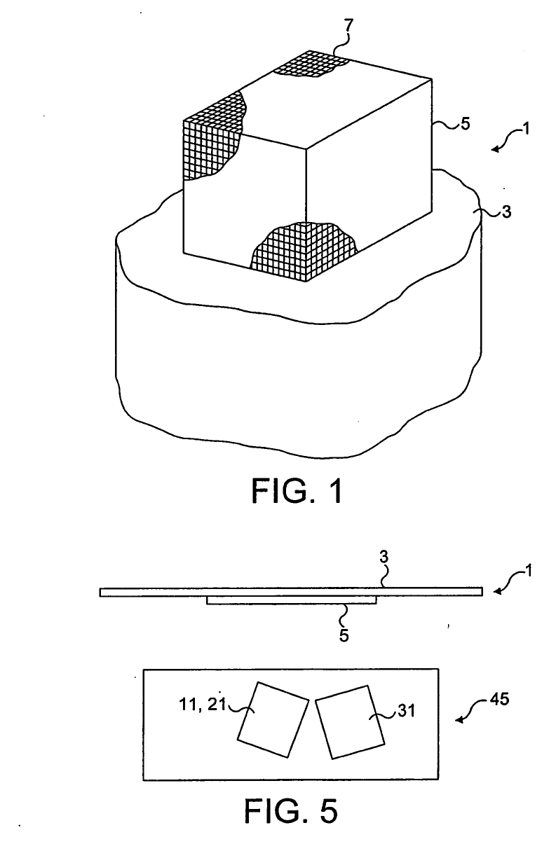

FIG. 1 illustrates a fragmentary view of a mail item in accordance with a preferred embodiment of the present invention;

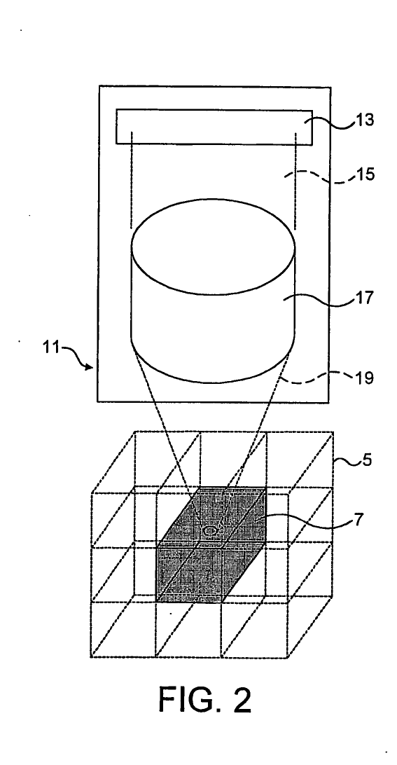

FIG. 2 schematically illustrates a data writer for writing to the mail item of FIG. 1 in accordance with a first embodiment of the present invention;

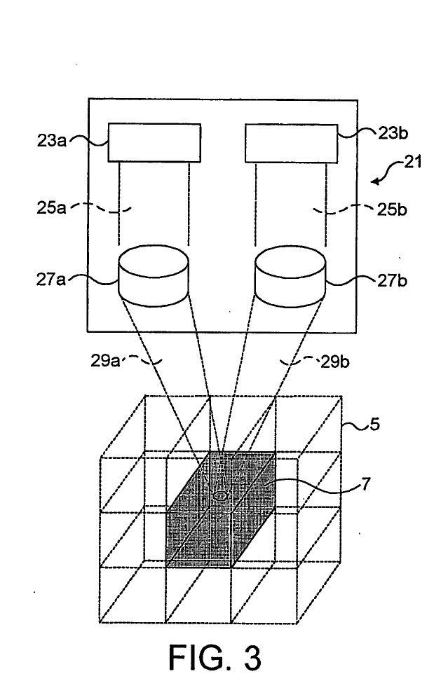

FIG. 3 schematically illustrates a data writer for writing to the mail item of FIG. 1 in accordance with a second embodiment of the present invention;

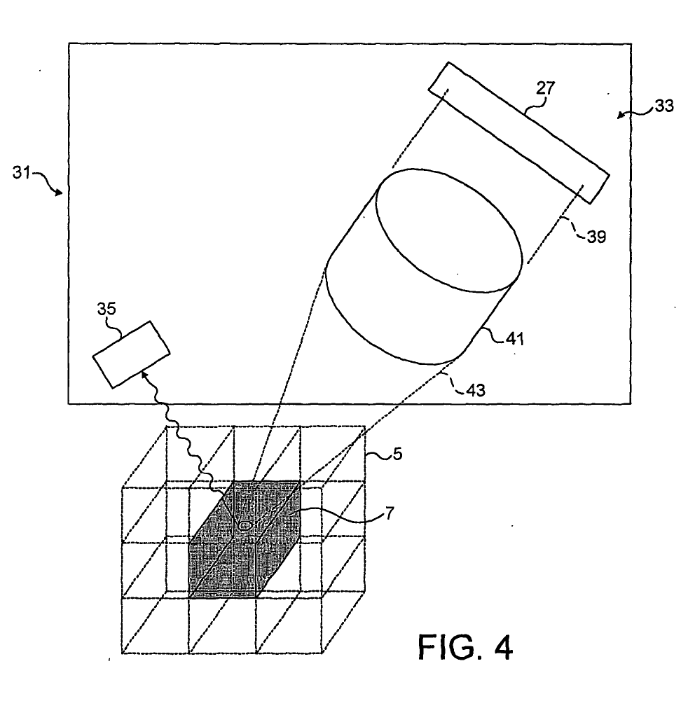

FIG. 4 schematically illustrates a data reader for reading from the mail item of FIG. 1 in accordance with a preferred embodiment of the present invention; and

FIG. 5 illustrates a mail handling system in accordance with a preferred embodiment of the present invention.

FIG. 1 illustrates a mail item 1 in accordance with a preferred embodiment of the present invention.

The mail item 1 comprises a body 3 and an information block 5, in this embodiment applied as a coating to the body 3, which provides a three-dimensional array of optically-addressable data elements 7 which are each individually writeable using a writing beam and readable using a reading beam. In an alternative embodiment the information block 5 could be formed as part of the body 3. As will be described in more detail hereinbelow, the data elements 7 are each addressable by directing a light beam at any addressable location within the information block 5.

In this embodiment the information block 5 is a continuous structure and the resolution of the data elements 7 is principally determined by the intensity of the writing beam and the optical spatial resolution, with the resolution being such as to avoid cross-talk between adjacent data elements 7 in writing and reading operations. The information block 5 can be conceptualized as a plurality of stacked pages, each comprising a two-dimensional array of addressable data elements 7.

In this embodiment the information block 5 comprises a carrier which includes throughout a photochromic storage material which has first and second states, and a readout material which provides an indication of the state of the storage material at its location. In this embodiment the storage material is a material which changes state from a first state to a second state in response to two-photon absorption, that is, the simultaneous absorption of two visible-light photons corresponding to ultraviolet (UV) light. In this embodiment the readout material is a material which is responsive to one-photon absorption.

In this embodiment the carrier is a polymeric material. In preferred embodiments the polymeric material comprises polyvinylbutyral, polymethylmethacrylate, doped polymethylmethacrylate, such as polymethylmethacrylate doped with 2-methyl-4-nitroaniline or polymethylmethacrylate doped with para-nitroaniline, polyvinylacetate, potassium dihydrogen phosphate, UV-curable urethane acrylate polymer or UV-curable epoxy polymer.

In this embodiment the storage material is a fulgide, which advantageously provides for thermal stability and relatively long data retention. In preferred embodiments the storage material comprises E-Adamantylidene [1-(2,5-dimethyl-3-furyl) ethylidene] succinic anhydride, 1-(2,5-dimethyl-3-furyl) ethylidene (isopropylidene) succinic anhydride, 2,3-bis(2,4,5-trimethyl-3-thienyl) maleic anhydride, cis-1,2-dicyano-1,2-bis(2,4,5-trimethyl-3-thienyl) ethene, 1,2-dicyano-1,2-bis(2-methylbenzothiophene-3-yl) ethene, or 2,3-bis(1,2-dimethyl-3-indolyl) maleic anhydride, and mixtures thereof.

In this embodiment the readout material comprises a fluorescent signal dye which fluoresces when illuminated only when the storage material is in a first state, and does not fluoresce, or fluoresces weakly, when illuminated when the storage material is in a second state. In preferred embodiments the signal material comprises 3,3′-diethyloxadicarbocyanine iodide, Nile Red dye, Pyridine-1, Pyridine-2,4-(dicyano methylene)-2-methyl-6-(p-dimethylamino styryl)-4 H-pyran, 2[4-(4-dimethylaminophenyl)-1,3-butadienyl]-3-ethylbenzothiazolium p-toluenesulfonate, or 1,1′,3,3,3′,3′-hexamethyl-4,4′,5,5′-dibenzo-2,2′,indotricarbocyanine perchlorate, and mixtures thereof.

In another embodiment the carrier can include throughout a frequency up-conversion material which enables data writing to be performed by light which has a wavelength which is other than the two-photon absorption wavelength of the storage material. The up-conversion material has efficient two-photon absorption at the operating wavelength of the light of the writing beam, and re-emits light at a wavelength region which is very efficient for converting the storage material from the first to the second state, such as from a colour state to a bleach state. For example, the writing beam can comprise infra-red light which is converted to visible light by the frequency up-conversion material. Preferred up-conversion materials are those based on second-harmonic generation or two-photon absorption-induced fluorescence. In preferred embodiments the up-conversion material comprises a frequency up-conversion dye, such as Coumarin 6, 8-hydroxyl-1,3 6-pyrenetrisulfonic acid or polymethylmethacrylate doped with a material having a high second order non-linear hyperpolarizability, such as 2-methyl-4-nitroaniline.

FIG. 2 illustrates a data writer 11 for writing to the information block 5 of the mail item 1 in accordance with a first embodiment of the present invention.

The data writer 11 comprises a light source 13 for providing a collimated light beam 15, and a lens 17 for focussing the collimated light beam 15 to provide a converging writing beam 19 which can be focussed at any location within the information block 5 of the mail item 1, and thereby provide for writing to any of the data elements 7 defined by the information block 5. In this embodiment the energy density of the writing beam 19 is insufficient to result in two-photon absorption at any location in the information block 5 other than at the location of the focal point of the writing beam 19. Thus, any of the data elements 7 can be individually addressed without effecting adjacent data elements 7, that is, without any cross-talk with adjacent data elements 7.

FIG. 3 illustrates a data writer 21 for writing to the information block 5 of the mail item 1 in accordance with a second embodiment of the present invention.

The data writer 21 comprises first and second light sources 23a, b for providing first and second collimated light beams 25a, b, and first and second lenses 27a, b for focussing the respective ones of the collimated light beams 25a, b to provide first and second converging writing beams 29a, b which can be focussed at any common location within the information block 5 of the mail item 1, and thereby provide for writing to any of the data elements 7 defined by the information block 5. In this embodiment the energy density of each of the writing beams 29a, b is alone insufficient to result in two-photon absorption at any location in the information block 5, but the first and second writing beams 29a, b together have sufficient energy density at the focussed common location to provide two-photon absorption. Thus, any of the data elements 7 can be individually addressed without effecting adjacent data elements 7, that is, without any cross-talk with adjacent data elements 7.

FIG. 4 illustrates a data reader 31 for reading from the information block 5 of the mail item 1 in accordance with a preferred embodiment of the present invention.

The data reader 31 comprises an illumination unit 33 for illuminating any location which corresponds to a data element 7 within the information block 5 of the mail item 1, and a detector 35 for detecting any signal from the illuminated data element 7, and thereby provide for reading from any of the data elements 7 defined by the information block 5.

The illumination unit 33 comprises a light source 37 for providing a collimated light beam 39, and a lens 41 for focussing the collimated light beam 39 to provide a converging reading beam 43 which can be focussed at any location within the information block 5 of the mail item 1, and thereby enable reading from the data element 7 at that location. In this embodiment the energy density of the reading beam 43 at the location of the focal point of the reading beam 43 is such as to provide for one-photon absorption. Thus, any of the data elements 7 can be individually addressed for reading without the possibility of cross-talk with adjacent data elements 7.

FIG. 5 illustrates a mail handling system 45 in accordance with a preferred embodiment of the present invention.

The mail handling system 45 comprises an information reader 31 as above described for reading information from the information block 5 of a mail item 1, with the three-dimensional array of the information block 5 defining a plurality of layers to which information can be written, and identifying the last written layer of the information block 5 in which information is stored, and an information writer 11, 21 as above described for writing new information in a subsequent layer of the three-dimensional array of the information block 5 as required. In one embodiment the information writer 11, 21 is configured such as to over-write the last written layer of the three-dimensional array of the information block 5 and thereby zeroise that layer.

With this configuration, the mail handling system 45 provides for the repeated use of mail items 1; the mail items 1 thereby being re-usable. In not requiring the marking of the mail items 1, such as by printing, to apply, for example, postage indicia, the mail items 1 conveniently provide for re-use.

Finally, it will be understood that the present invention has been described in its preferred embodiments and can be modified in many different ways without departing from the scope of the invention as defined by the appended claims.

1. A mail item incorporating an information block which provides a three-dimensional array of addressable data elements for storing information, wherein the three-dimensional array defines a plurality of layers to which information can be written.

2. The mail item of claim 1, wherein the information block comprises a carrier including a photochromic storage material having first and second states, and a readout material for providing an indication of the state of the storage material at its location.

3. The mail item of claim 1, wherein the stored information includes encoded information.

4. The mail item of claim 3, wherein the encoded information is encrypted information.

5. The mail item of claim 3, wherein the encoded information is cryptographically-signed information.

6. The mail item of claim 1, wherein the information block comprises an applied coating.

7. The mail item of claim 1, wherein the information block defines at least part of a body of the mail item.

8. The mail item of claim 1, wherein the mail item comprises a container.

9. The mail item of claim 1, wherein the mail item comprises an envelope.

10. The mail item of claim 1, wherein the mail item is re-usable, such that, on each use, information is written to a different layer of the information block.

11. Use, as a re-usable item, of a mail item incorporating an information block which provides a three-dimensional array of addressable data elements for storing information, with the three-dimensional array defining a plurality of layers to which information can be written.

12. A mail handling system, comprising:
an information reader for reading information from an information block, as a three-dimensional array of addressable data elements, incorporated in a mail item, with the three-dimensional array defining a plurality of layers to which information can be written, and identifying the last written layer in which information is stored; and
an information writer for writing new information in a subsequent layer of the three-dimensional array of the information block.

13. The mail handling system of claim 12, wherein the information writer is configured such as to over-write the last written layer of the three-dimensional array of the information block and thereby zeroise that layer.
